(19) United States
(12) Patent Application Publication
(10) Pub. No.: US 2007/0169795 A1
(43) Pub. Date: Jul. 26, 2007

(54) Apparatus for cleaning substrates

(76) Inventors: Hun-Jung Yi, Suwon-si (KR); Sang-Oh Park, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/656,446

(22) Filed: Jan. 23, 2007

(30) Foreign Application Priority Data
Jan. 23, 2006 (KR) 2006-06871

(51) Int. Cl. C23G 1/00; B08B 3/00; H01L 21/306

(52) U.S. Cl. 134/94.1; 134/2; 156/345.11

(57) ABSTRACT

An apparatus for cleaning substrates includes a supporting member supporting substrates in an upright position, and a liquid supplying member including a first nozzle disposed at one side of a vertical centerline of the substrates, and a second nozzle is disposed at another side of the vertical centerline of the substrates. Each of the first and second nozzles may include first injection holes to inject cleaning liquid toward lower ends of the substrates or regions adjacent to the lower ends of the substrates.

### SUMMARY OF THE INVENTION

The invention is therefore directed to a substrate cleaning apparatus that substantially overcomes one or more of the problems due to the limitations and disadvantages of the related art.

It is a feature of an embodiment of the present invention to provide a substrate cleaning apparatus that may perform efficient cleaning of a substrate.

It is another feature of an embodiment of the present invention to provide a substrate cleaning apparatus that may increase etch uniformity across a wafer.

At least one of the above and other features and advantages of the present invention may be realized by providing an apparatus for cleaning a substrate that may include a supporting member supporting substrates in an upright position, and a liquid supplying member including a first nozzle disposed at one side of a vertical centerline of the substrates, and a second nozzle disposed at another side of the vertical centerline of the substrate. Each of the first and second nozzles may include multiple first injection holes to inject cleaning liquid toward lower ends of the substrates or regions adjacent to the lower ends of the substrates.

Each of the first and second nozzles may further include multiple second injection holes so as to inject cleaning liquid toward lateral or outermost ends of the substrates or regions adjacent to the lateral or outermost ends of substrates. Each of the first and second nozzles may further include multiple third injection holes to inject cleaning liquid toward upper ends of the substrates or regions adjacent to the upper ends of the substrates.

The supporting member may be provided with a supporting rod supporting the substrates at portions adjacent to lateral ends of the substrates. Each of the first and second nozzles may further include multiple second injection holes so as to inject cleaning liquid toward an inner end of the supporting rod or a region adjacent to the inner end.

Each of the first and second injection holes may have a gradually increasing cross-section in a cleaning liquid injection direction, and each of the third injection holes may have a uniform cross-section in a cleaning liquid injection direction. Alternatively, each of the first injection holes may have a gradually increasing cross-section in a cleaning liquid injection direction.

At least one of the above and other features and advantages of the present invention may be realized by providing a method for cleaning a substrate that may include supporting substrates in an upright position on a supporting member, and injecting cleaning liquid toward the substrates via a liquid supplying member that may include a first nozzle disposed at one side of a vertical centerline of the substrates, and a second nozzle that may be disposed at another side of the vertical centerline of the substrates. Each of the first and second nozzles may include multiple first injection holes to inject cleaning liquid toward lower ends of the substrates or regions adjacent to the lower ends of the substrates.

Injecting cleaning liquid toward outermost regions of the substrates or regions adjacent to the outermost regions without interference with the supporting member may be via multiple second injection holes, and injecting cleaning liquid toward upper ends of the substrates or regions adjacent to the upper ends of the substrates may be via multiple third injection holes. Each of the first and second injection holes may have a gradually increasing cross-section in a cleaning liquid injection direction. Injecting cleaning liquid toward lateral ends of the substrates or in a substantially tangential direction of the substrates may be via multiple of second injection holes, and injecting cleaning liquid toward upper ends of the substrates may be via multiple third injection holes.

### BRIEF DESCRIPTION OF THE DRAWINGS

The above and other features and advantages of the invention will become more apparent to those of ordinary skill in the art by describing in detail exemplary embodiments thereof with reference to the attached drawings, in which:

FIG. 1 illustrates a schematic view of a related art substrate cleaning apparatus;

FIG. 2 illustrates paths of injected cleaning liquid in the substrate cleaning apparatus depicted in FIG. 1;

FIG. 3 illustrates a schematic view of a substrate cleaning apparatus according to an embodiment of the invention;

FIG. 4 illustrates a perspective view of a supporting member of the substrate cleaning apparatus depicted in FIG. 3;

FIG. 5 illustrates a perspective view of a nozzle of the substrate cleaning apparatus depicted in FIG. 3;

FIG. 6 illustrates a view of injection angles of injection holes formed in nozzles of the substrate cleaning apparatus depicted in FIG. 3, according to an embodiment of the invention;

FIG. 7A illustrates a sectional view of the nozzle depicted in FIG. 5 according to an embodiment of the invention;

FIG. 7B illustrates a sectional view of the nozzle depicted in FIG. 5 according to another embodiment of the invention;

FIG. 8 illustrates a sectional view of the nozzle depicted in FIG. 5 according to another embodiment of the invention;

FIG. 9 illustrates a view for of injection angles of injection holes formed in the nozzles of the substrate cleaning apparatus depicted in FIG. 3, according to another embodiment of the invention;

FIG. 10 illustrates a view for of injection angles of injection holes formed in the nozzles of the substrate cleaning apparatus depicted in FIG. 3, according to another embodiment of the invention;

FIG. 11 illustrates a schematic view of a substrate cleaning apparatus according to another embodiment of the invention; and

FIG. 12 illustrates a schematic view of a substrate cleaning apparatus according to another embodiment of the invention.

### DETAILED DESCRIPTION OF THE INVENTION

Korean Patent Application No. 2006-06871 filed on Jan. 23, 2006, in the Korean Intellectual Property Office, and entitled: “Apparatus for Cleaning Substrates,” is incorporated by reference herein in its entirety.

The invention will now be described more fully hereinafter with reference to the accompanying drawings, in which exemplary embodiments of the invention may be illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

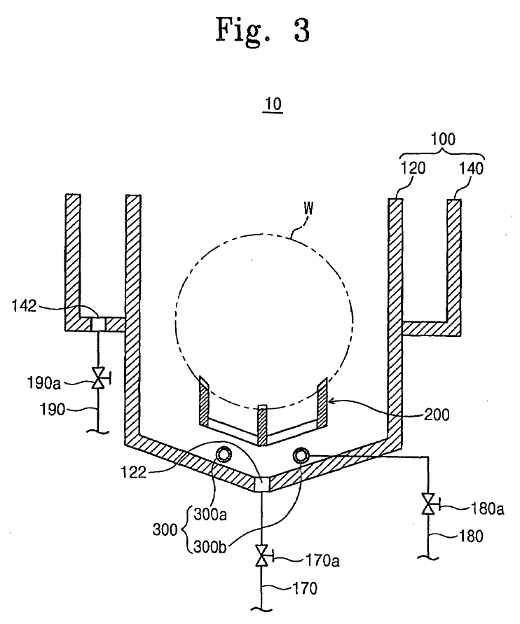

Hereinafter, embodiments of the invention will be described in conjunction with FIGS. 3 through 12.

FIG. 3 illustrates a schematic view of a substrate cleaning apparatus 10 according to an embodiment of the invention. The substrate cleaning apparatus 10 may clean multiple wafers (W). The substrate cleaning apparatus 10 may include a treating room 100, a supporting member 200, and a liquid supplying member 300. The treating room 100 may accommodate wafers (W) and may provide a processing space for the wafers (W). The supporting member 200 may support the wafers (W) in the treating room 100. The liquid supplying member 300 may supply process liquid to the treating room 100.

For example, the liquid may be cleaning liquid, e.g., deionized water, for removing remaining chemical solutions from the wafers (W). The liquid may also be a chemical solution, e.g., a phosphate solution, a hydrofluoric acid solution, a sulfuric acid solution, or an ammonium hydroxide solution. The liquid may be used for removing contaminants such as remaining films, residues, organic substances, or particles from the wafers (W). The apparatus may also be suitable for multiple cleaning protocols such as RCA clean, which may include an organic clean, an oxide strip and an ionic clean. Furthermore, the liquid may be inert gas (e.g., nitrogen) or alcohol vapor (e.g., isopropyl alcohol vapor) for drying wafers (W).

The currently described embodiment of the invention describes an apparatus that may remove chemical solutions from wafers (W) using cleaning liquid, e.g., a rinsing solution or a chemical solution. The above-described elements will now be more fully described.

The treating room 100 may include an inner tub 120 with an open top and an outer tub 140, surrounding the inner tub 120, to receive cleaning liquid overflowing from the inner tub 120. The inner tub 120 may include a drain hole 122 in a bottom surface to discharge the cleaning liquid from the inner tub 120. A drain tube 170 having a valve 170a may connect to the drain hole 122. The outer tub 140 may include a drain hole 142 in a bottom surface to discharge the cleaning liquid from the outer tub 140. A drain tube 190 having a valve 190a may connect to the drain hole 142.

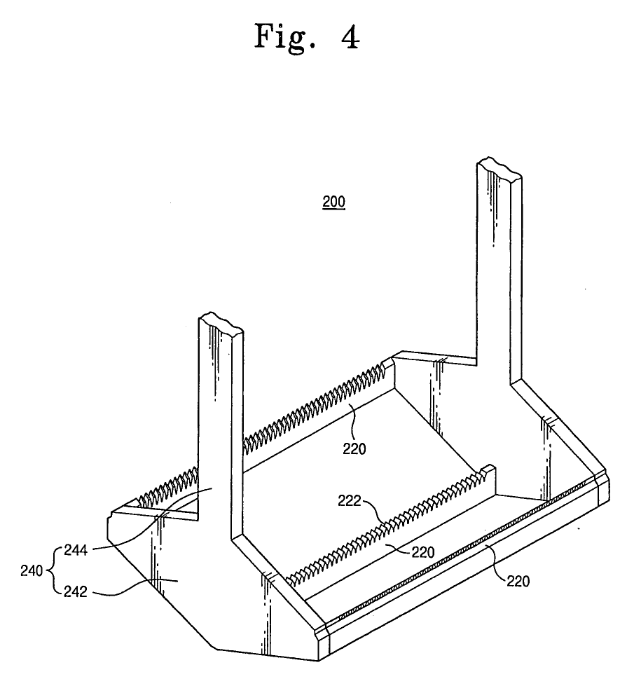

The supporting member 200 may be disposed in the inner tub 120 to support wafers (W) during the cleaning process. Referring to FIG. 4, the supporting member 200 may include supporting rods 220 and side plates 240. Each of the supporting rods 220 may be formed with slots 222 such that edges of wafers (W) may be inserted into the slots 222. During the cleaning process, the supporting member 200 may be positioned such that the wafers (W) may be arranged in a row in an upright position. The wafers (W) may be arranged in the same direction as the slots 222 are formed. The number of the supporting rods 220 may be about three, and about fifty wafers (W) may be placed on the supporting member 200. The side plates 240 may be formed on both sides of the supporting rods 220 to connect the supporting rods 220 and fix the supporting member 200 to the treating room 100. Each of the side plates 240 may include a connecting portion 242 to which ends of the supporting rods 200 may be fixed. A rod-shaped fixing portion 244 may extend upwardly from the connecting portion 242 for fixing to the treating room 100. Alternatively, instead of being fixed to the treating room 100, the supporting member 200 may be moved up and down by a lifting unit (not shown).

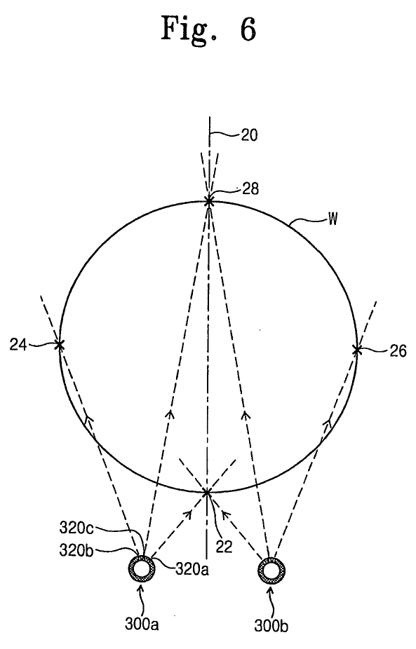

The liquid supplying member 300 may supply cleaning liquid to the inner tub 120. The liquid supplying member 300 may include a first nozzle 300a and a second nozzle 300b. The first nozzle 300a may be disposed at one side (the left side in FIG. 3) of a vertical centerline 20 (refer to FIG. 6). The second nozzle 300b may be disposed at the other side (the right side in FIG. 3) of the vertical centerline 20. The first nozzle 300a may supply cleaning liquid to the left half side of a wafer (W), and the second nozzle 300b may supply cleaning liquid to the right half side of the wafer (W).

A supplying tube 180 may supply cleaning liquid to the liquid supplying member 300 from outside the treating room 100. A valve 180a may be installed in the supplying tube 180 to open and close the supplying tube 180 and/or to adjust the flow rate of the cleaning liquid flowing through the supplying tube 180. When a chemical solution is used as the cleaning liquid, the chemical solution discharging from the outer tub 140 may be reused. In this case, the supplying tube 180 may connect to the drain tube 190 connected to the outer tub 140. Further, a pump (not shown), a filter (not shown), and/or a heater (not shown) may be installed in connection with the drain tube 190 or the supplying tube 180. The pump may force the chemical solution from the drain tube 190 to the supplying tube 180, and the filter may remove foreign substances from the recirculating chemical solution. The heater may heat the recirculating chemical solution to the process temperature of the inner tub 120.

The structure of the first and second nozzles 300a and 300b will now be described in detail. The first and second nozzles 300a and 300b may be symmetrically disposed with respect to the vertical centerline 20 of the wafer (W). The following description concentrates on the first nozzle 300a. Description of the second nozzle 300b will be omitted as being repetitive of the description of the first nozzle 300a.

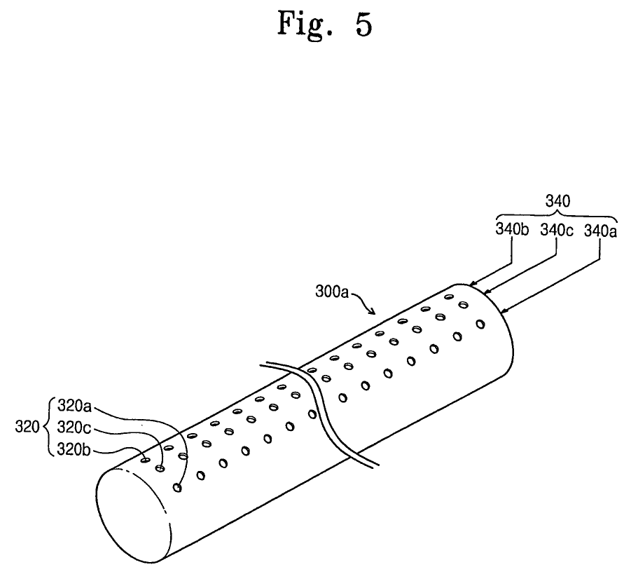

FIG. 5 illustrates a perspective view of the first nozzle 300a, and FIG. 6 illustrates a view of injection angles of injection holes formed in the first and second nozzles 300a and 300b. In FIG. 5, the first nozzle 300a may have a long rod shape. The nozzle 300a may have a cross-sectional profile that may be circular, oval, rectangular or square. The first nozzle 300a may be positioned along the arranged direction of wafers (W). The first nozzle 300a may be formed with multiple injection holes 320. The injection holes 320 may be arranged in three rows 340. Each of the injection hole rows 340 may preferably include about fifty injection holes 320 or more. The invention may also use between about 20 and about 100 holes. Each of the injection holes 320 may have a diameter of about 1 mm or less. Among the three injection hole rows 340, an innermost row from the vertical centerline 20 will be referred to as a first row 340a, and an outermost row from the vertical centerline 20 will be referred to as a second row 340b. A row between the first and second rows will be referred to as a third row 340c. Also, the injection holes of the first row 340a will be referred to as first injection holes 320a, the injection holes of the second row 340b as second injection holes 320b, and the injection holes of the third row 340c as third injection holes 320c.

As shown in FIG. 6, cleaning liquid may be directly injected to a lower end 22, a lateral end and an upper end 28 of a wafer (W) from the first injection hole 320a, the second injection hole 320b, and the third injection hole 320c, respectively. The lower end 22, and its neighboring region, may be treated mainly by the cleaning liquid injected through the first injection hole 320a, and the lateral end, and its neighboring region, may be treated mainly by the cleaning liquid injected through the second injection hole 320b. Further, the upper end 28 and its neighboring region may be treated mainly by the cleaning liquid injected through the third injection hole 320c. Alternatively, cleaning liquid may be injected to the neighboring region of the lower end 22, the neighboring region of the lateral end, and the neighboring region of the upper end 28 from the first injection hole 320a, the second injection hole 320b, and the third injection hole 320c, respectively. Here, the lateral end of the wafer (W) that receives the cleaning liquid from the second injection hole 320b of the first nozzle 300a may be a left end 24 of the wafer (W). Also, a right end 26 of the lateral end of the wafer (W) may receive cleaning liquid from a second injection hole 320b of the second nozzle 300b.

Therefore, the left half side of the wafer (W) including the lower end 22, the upper end 28, and the left end 24 may mainly be treated by the cleaning liquid injected by the first nozzle 300a, and the right half side of the wafer (W) including the lower end 22, the upper end 28, and the right end 26 may mainly be treated by the cleaning liquid injected by the second nozzle 300b.

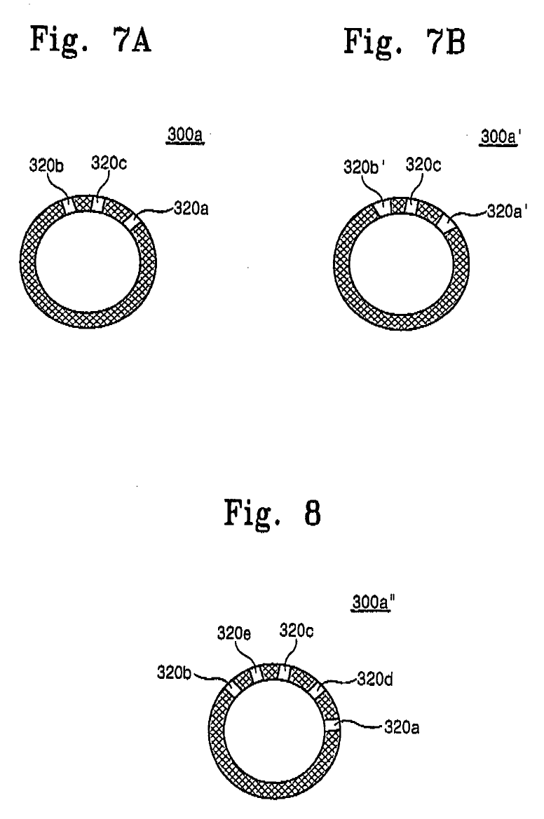

FIG. 7A illustrates a sectional view of injection holes formed in the first nozzle 300a according to an embodiment of the invention, and FIG. 7B illustrates a sectional view of injection holes formed in a first nozzle 300a′ according to another embodiment of the invention. Referring to FIG. 7A, the first nozzle 300a may include a first injection hole 320a, a second injection hole 320b, and a third injection hole 320c. Each of the first to third injection holes 320a, 320b, and 320c may be uniformly formed along the liquid injecting direction. In this structure, cleaning liquid may be injected to a wafer (W) through the first to third injection holes 320a, 320b, and 320c at high pressure.

In comparison, FIG. 7B illustrates a first injection nozzle 300a′ that may include a first injection hole 320a′ and a second injection hole 320b′ that have a gradually increasing size, i.e., the nozzles may be tapered. That is, each of the first and second injection holes, 320a′ and 320b′ may increase in size along the liquid injecting direction from the inside to the outside of the injection nozzle 300a′. The first injection nozzle 300a′ may further include the third injection hole 320c having a uniform diameter along the liquid injecting direction. The distance between the first injection hole 320a and the lower end 22 of the wafer and the distance between the second injection hole 320b and the lateral end 24 of the wafer (W) may be relatively short. The shape of the first and second injection holes 320a′ and 320b′ may allow the cleaning liquid to be injected over a wide area rather than to a distant area. Further, the distance between the third injection hole 320c and the upper end of the wafer (W) may be relatively long. The shape of the third injection hole 320c may allow the cleaning liquid to be injected to a distant area rather than over a wide area.

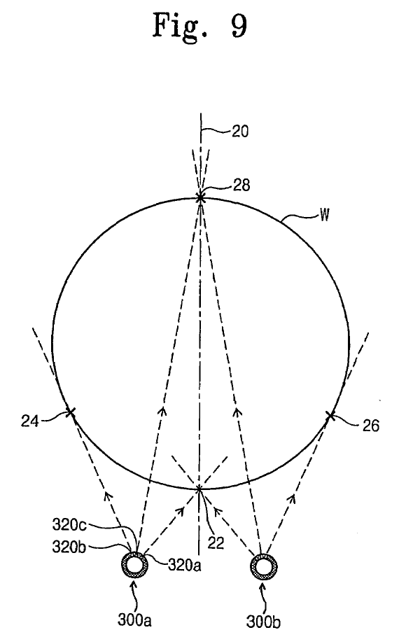

In the above-described embodiments of the invention, the injection holes 320 may be arranged in three rows. However, as shown in FIG. 8, a first nozzle 300a″ may include the first injection hole 320a, the second injection hole 320b, the third injection hole 320c, a fourth injection hole 320d between first and third injection holes 320a and 320c, and a fifth injection hole 320e between second and third injection holes 320b and 320c. While diameters of these injection holes are illustrated as uniform, any or all may be tapered.

Referring again to FIG. 6, the second injection hole 320b of the first nozzle 300a may inject cleaning liquid to the lateral end 24 of the wafer (W). However, as shown in FIG. 9, the second injection hole 320b of the first nozzle 300a may inject cleaning liquid in a tangential direction of the wafer (W) or in a direction similar to the tangential direction. That is, the cleaning liquid may be injected in a substantially tangential direction.

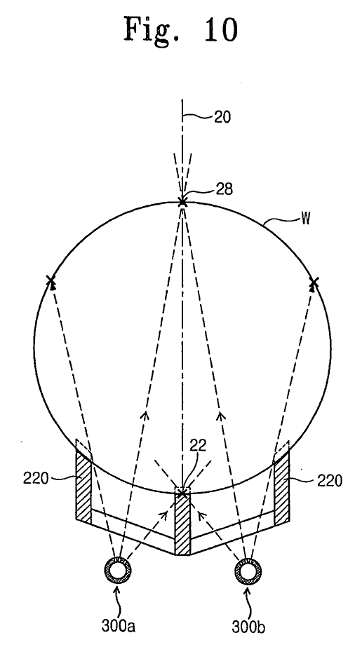

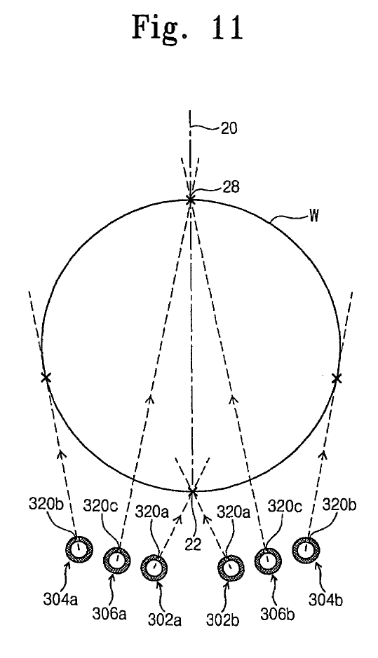

Further, the supporting rod 220 (which may be also called the supporting member) may be positioned in the path of the cleaning liquid injected from the second injection hole 320b of the first nozzle 300a depending on the location of the first nozzle 300a. In this case, the cleaning liquid may fail to reach the wafer (W) because of the obstructing supporting rod 220. To prevent this situation, the second injection hole 320b may be formed to inject cleaning liquid close to the lateral end of the wafer (W) without being obstructed by the supporting rod 220, as shown in FIG. 10. For example, cleaning liquid injected from the second injection hole 320b may pass through a region immediately adjacent to an inner surface of the outermost supporting rod 220 and then reaches the wafer (W).

Furthermore, in the above-described embodiments, the first nozzle 300a and the second nozzle 300b may be respectively disposed at one side and the other side of the vertical centerline 20 of a wafer (W). However, multiple nozzles may be disposed at each side of the vertical centerline 20 of a wafer (W), as may be shown in FIG. 11. For example, three nozzles may be disposed at each side of the vertical centerline 20 of the wafer (W) for a total of six nozzles. However, the multiple nozzle embodiments of the invention may not be restricted to a total of six nozzles, and any appropriate number of nozzles may be used. The two nozzles closest to the vertical centerline 20 will be referred to as first nozzle (1) 302a and second nozzle (1) 302b. The most distant two nozzles from the vertical centerline 20 will be referred to as first nozzle (2) 304a and second nozzle (2) 304b. The nozzle disposed between the first nozzle (1) 302a and the first nozzle 304a (2) will be referred to as first nozzle (3) 306a, and the nozzle disposed between the second nozzle (1) 302b and the second nozzle (2) 304b as second nozzle (3) 306b. In this case, first injection holes 320a may be formed in the first nozzle (1) 302a and the second nozzle (1) 302b, and second injection holes 320b may be formed in the first nozzle (2) 304a and the second nozzle (2) 304b. Third injection holes 320c may be formed in the first nozzle (3) 306a and the second nozzle (3) 306b.

Alternatively, two nozzles may be disposed at each side of the vertical centerline 20 of the wafer (W). In this case, first injection holes 320a may be formed in the closest nozzle to the vertical center line 20 of wafer (W) to inject cleaning liquid to the lower end 22 of the wafer (W) or a neighboring region of the lower end 22. Second injection holes 320b may be formed in the most distant nozzle from the vertical center line 20 of the wafer (W) to inject cleaning liquid to the lateral end of the wafer (W) or a neighboring region of the lateral end. Third injection holes 320c may be formed in the closest nozzle to the vertical centerline 20, the most distant nozzle from the vertical centerline 20. In these multiple nozzle configurations, the nozzles may be rotated to adjust the angle of liquid flow relative to the wafer.

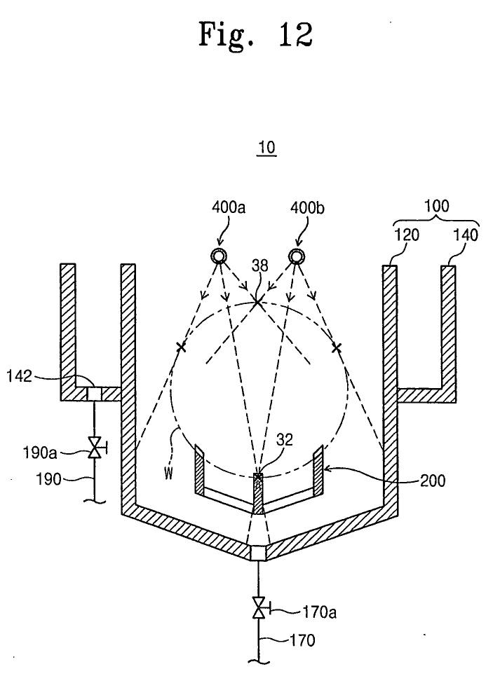

FIG. 12 illustrates a schematic view of a substrate cleaning apparatus according to another preferred embodiment of the invention. Referring to FIG. 12, a first nozzle 400a and a second nozzle 400b may be disposed above a wafer (W). The first nozzle 400a may include multiple injection holes arranged in three rows. First injection holes may be arranged in a first row, second injection holes may be arranged in a second row, and third injection holes may be arranged in a third row. Cleaning liquid may be injected from the first injection holes toward an upper end 38 of the wafer (W) or a region neighboring the upper end 38. Further, cleaning liquid may be injected from the second injection holes toward a lateral end of the wafer (W), or a region neighboring the lateral end. Furthermore, cleaning liquid may be injected from the third injection holes toward a lower end 32 of the wafer (W) or a region neighboring region the lower end 32. Alternatively, injection holes may be formed in the first nozzle 400a to inject cleaning liquid in a direction substantially tangential to the wafer (W). The injection holes may be formed in the same way as in FIG. 7A, 7B, or 8.

In FIGS. 6 and 12, the nozzles may be disposed under or above the wafer (W). However, the nozzles may be disposed at other locations.

In a cleaning process using the substrate cleaning apparatus of FIG. 3, a chemical solution, e.g., a hydrofluoric acid solution, may be supplied to the inside of the inner tub 120 from the first and second nozzle 300a and 300b to fill the inner tub 120. Next, wafers (W) may be placed on the supporting member 200, and the chemical solution may be also supplied to the inner tub 120. The chemical solution overflowing from the inner tub 120 may be received by the outer tub 140 and may then be discharged to the outside. After that, rinsing liquid, e.g., deionized water, may be supplied to the inner tub 120 from the first and second nozzles 300a and 300b. The chemical solution in the inner tub 120 may be replaced with deionized water, and the remaining chemical solution on the wafers (W) may be removed.

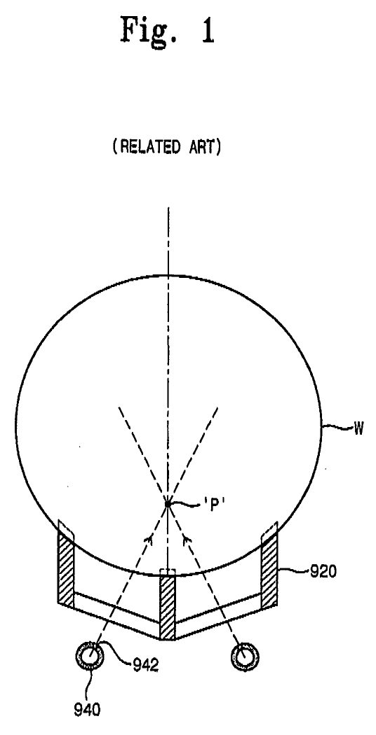

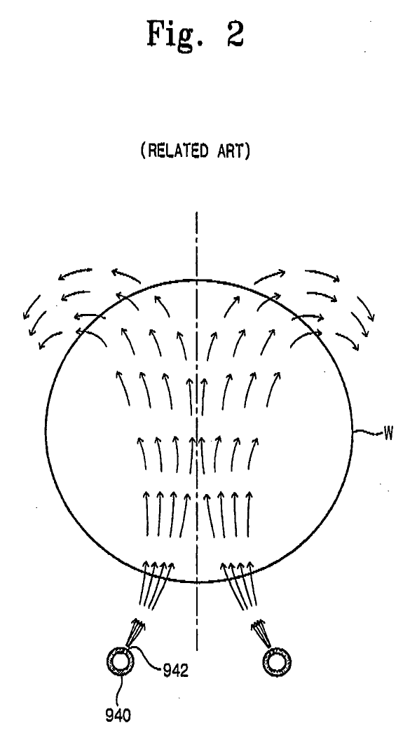

Wafers (W) may be cleaned by injecting deionized water using related art nozzles 942 of FIG. 1, and wafers (W) may be cleaned under the same conditions by injecting deionized water using the nozzles 300a and 300b shown in FIG. 5. Then, the two cases may be compared in Tables 1 and 2 to evaluate the etching uniformity across one wafer (W) compared to multiple wafers (W). Fifty wafers (W) may be placed on the supporting member in a row, and then the fifty wafers (W) may be cleaned. The first and second nozzles 300a and 300b may be disposed as shown in FIG. 10, and deionized water may be used as the cleaning liquid to remove a chemical solution (hydrofluoric acid solution) from the fifty wafers (W). The fifty wafers (W) may be called the first wafer W₁, the second wafer W₂, the third wafer W₃, . . . , and the fiftieth wafer W₅₀, respectively.

In Table 1, Eᵤ₁ denotes a standard deviation of etched amounts of all regions of each wafer (W) when the related art nozzles 942 were used, and Eᵤ₂ denotes a standard deviation of etched amounts of all regions of each wafer (W) when the nozzles 300a and 300b of the invention were used.

TABLE 1

| | W₁ | W₂ | W₅₀ |
|---|---|---|---|
| Eᵤ₁ | 3.6 | 6.1 | 14.6 |
| Eᵤ₂ | 3.1 | 3.4 | 4.4 |

In Table 1, the standard deviation of the etched amounts of each wafer (W) may be reduced when the nozzles 300a and 300b of the invention are used as compared to the conventional nozzles 942. That is, etching uniformity across one wafer (W) may improve when the nozzles 300a and 300b of the invention are used. Since deionized water may effectively be supplied to the entire area of each wafer (W) from the nozzles 300a and 300b, hydrofluoric acid solution may be uniformly removed from the entire area of each wafer (W), thereby improving the etching uniformity across each wafer (W).

In Table 2, Eₘ₁ denotes an average etched amount of all regions of each wafer (W) when the conventional nozzles 942 were used, and Eₘ₂ denotes an average etched amount of all regions of each wafer (W) when the nozzles 300a and 300b of the invention were used.

TABLE 2

| | W₁ | W₂ | W₅₀ |
|---|---|---|---|
| Eₘ₁(Å) | 29.5 | 28.5 | 30 |
| Eₘ₂(Å) | 29.9 | 29.1 | 29.6 |

Referring to Table 2, the differences between the average values are not large (when comparing W₁, W₂ and W₅₀, which ranges from 29.1 to 29.6) when the nozzles 300a and 300b of the invention are used as compared with the conventional nozzles 942 (when comparing W₁, W₂ and W₅₀, which ranges from 28.5 to 30). That is, etching uniformity across the wafers (W) may improve when the nozzles 300a and 300b of the invention are used. Since deionized water may be uniformly supplied to all the wafers (W) when the nozzles 300a and 300b of the invention are used, the etching uniformity across all the wafers (W) may be improved.

As described above, when the nozzle of the invention is used, a wafer (W) may be uniformly cleaned.

Further, when the nozzle of the invention is used, multiple wafers (W) may be uniformly cleaned.

Exemplary embodiments of the invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the invention as set forth in the following claims.

What is claimed is:

1. An apparatus for cleaning substrates, comprising:
a supporting member for supporting substrates in an upright position; and
a liquid supplying member including a first nozzle disposed at one side of a vertical centerline of the substrates, and a second nozzle disposed at another side of the vertical centerline of the substrates,
wherein each of the first and second nozzles includes a plurality of first injection holes to inject cleaning liquid toward lower ends of the substrates or regions adjacent to the lower ends of the substrates.

2. The apparatus as claimed in claim 1, wherein each of the first and second nozzles further includes a plurality of second injection holes to inject cleaning liquid toward outermost regions of the substrates or regions adjacent to the outermost regions.

3. The apparatus as claimed in claim 2, wherein each of the first and second nozzles further includes a plurality of third injection holes to inject cleaning liquid toward upper ends of the substrates or regions adjacent to the upper ends of the substrates.

4. The apparatus as claimed in claim 1, wherein each of the first and second nozzles further includes a plurality of second injection holes to inject cleaning liquid toward lateral ends of the substrates or regions adjacent to the lateral ends of substrates.

5. The apparatus as claimed in claim 1, wherein the supporting member comprises at least one supporting rod to support the substrates at portions adjacent to lateral ends of the substrates; and
each of the first and second nozzles further includes a plurality of second injection holes to inject cleaning liquid toward an inner end of the at least one supporting rod or a region adjacent to the inner end.

6. The apparatus as claimed in claim 5, wherein each of the first and second nozzles further includes a plurality of third injection holes to inject cleaning liquid toward upper ends of the substrates or regions adjacent to the upper ends of the substrates.

7. The apparatus as claimed in claim 1, wherein each of the first injection holes has a gradually increasing cross-section in a cleaning liquid injection direction.

8. The apparatus as claimed in claim 1, wherein each of the first and second nozzles further includes a plurality of second injection holes to inject cleaning liquid in a substantially tangential direction of the substrates.

9. The apparatus as claimed in claim 8, wherein each of the first and second nozzles further includes a plurality of third injection holes to inject cleaning liquid toward upper ends of the substrates or regions adjacent to the upper ends of the substrates.

10. The apparatus as claimed in claim 1, wherein the substrates are placed on the supporting member in a row, and the first and second nozzles are disposed parallel to the row.

11. The apparatus as claimed in claim 1, wherein the cleaning liquid is a chemical solution or a rinsing liquid.

12. The apparatus as claimed in claim 1, wherein the first and second nozzles are disposed above the substrates that are supported on the supporting member.

13. The apparatus as claimed in claim 1, wherein the first and second nozzles are disposed under the supporting member.

14. The apparatus as claimed in claim 1, wherein each of the first and second nozzles includes:
a plurality of second injection holes to inject cleaning liquid toward outermost regions of the substrates or regions adjacent to the outermost regions without interference with the supporting member; and
a plurality of third injection holes to inject cleaning liquid toward upper ends of the substrates or regions adjacent to the upper ends of the substrates.

15. The apparatus as claimed in claim 14, wherein each of the first and second injection holes has a gradually increasing cross-section in a cleaning liquid injection direction.

16. The apparatus as claimed in claim 1, wherein each of the first and second nozzles includes:
a plurality of second injection holes to inject cleaning liquid toward lateral ends of the substrates or in a substantially tangential direction of the substrates; and
a plurality of third injection holes to inject cleaning liquid toward upper ends of the substrates.

17. A cleaning method, comprising:
supporting substrates in an upright position on a supporting member; and
injecting cleaning liquid toward the substrates via a liquid supplying member including a first nozzle disposed at one side of a vertical centerline of the substrates, and a second nozzle disposed at another side of the vertical centerline of the substrates,
wherein each of the first and second nozzles includes a plurality of first injection holes to inject the cleaning liquid toward lower ends of the substrates or regions adjacent to the lower ends of the substrates.

18. The cleaning method as claimed in claim 17, further comprising:
injecting the cleaning liquid toward outermost regions of the substrates or regions adjacent to the outermost regions without interference with the supporting member via a plurality of second injection holes; and
injecting the cleaning liquid toward upper ends of the substrates or regions adjacent to the upper ends of the substrates via a plurality of third injection holes.

19. The cleaning method as claimed in claim 18, wherein each of the first and second injection holes has a gradually increasing cross-section in a cleaning liquid injection direction.

20. The cleaning method as claimed in claim 17, further comprising:
injecting the cleaning liquid toward lateral ends of the substrates or in a substantially tangential direction of the substrates via a plurality of second injection holes; and
injecting the cleaning liquid toward upper ends of the substrates via a plurality of third injection holes.
